(19) United States
(12) Patent Application Publication
(10) Pub. No.: US 2004/0102861 A1
(43) Pub. Date: May 27, 2004

(54) Computer system and method controlling audio signal outputs of application programs

(75) Inventor: Jae-jin Han, Suwon-City (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-City (KR)

(21) Appl. No.: 10/453,659

(22) Filed: Jun. 4, 2003

(30) Foreign Application Priority Data
Nov. 27, 2002 (KR) 2002-74426

(51) Int. Cl. G06F 17/00; H03G 3/00

(52) U.S. Cl. 700/94; 381/61

(57) ABSTRACT

A method of controlling a computer system having an audio reproducing part receiving audio signals from a plurality of application programs generating the audio signals and only reproducing the audio signals of the application programs selected. The computer displays a selection menu from which an application program generating an audio signal desirous of being reproduced is allowed to be selected from among the application programs generating the audio signals. Therefore, only the audio signal from the application program selected is supplied to the audio reproducing part.

### CROSS-REFERENCE TO RELATED APPLICATIONS

This application claims the benefit of Korean Patent Application No. 2002-74426, filed Nov. 27, 2002, in the Korean Intellectual Property Office, the disclosure of which is incorporated herein by reference.

### BACKGROUND OF THE INVENTION

1. Field of the Invention

The present invention relates, in general, to a computer system and a method of controlling the same, and more particularly, to a computer system equipped with a sound card which is driven by a sound card driver and then selectively receives and reproduces an audio signal generated from among a plurality of application programs, and a method of controlling the computer system.

2. Description of the Related Art

Recently, because of popularity of representing multimedia information through a variety of media, such as moving pictures, pictures, music, etc., most computer users have installed multimedia units in their computer systems. Especially, a sound card has usually been installed inside the main body of the computer system to reproduce music from an MP3 file or a CD, or to reproduce sound in connection with moving pictures to enjoy, for example, a game or a movie, and a speaker or a headset is connected to the sound card to output the sound.

The sound card generally comprises a main DSP chip, a CODEC, and input and output terminals. The main DSP chip, referred to as a sound chip, plays the most important role in the sound card by synthesizing and coordinating the sound. The CODEC converts an analog signal into a digital signal or a digital signal into an analog signal. In the case of sound output, the digital sound data processed in the main DSP chip of the sound card is converted through the CODEC into analog data, allowing a person to hear the sound. Therefore, the digital signal processed internally is modulated to an analog signal which is then amplified through a speaker whereby a person can hear the sound. On the other hand, in the case of sound input, the analog signal input to the sound card through a microphone is modulated to a digital signal by the CODEC and then processed through the DSP (sound) chip.

A sound card driver controls the sound card. In response to execution of an application program (for example, a Windows Media Player or a game program and so on) based on an operating system, the sound card driver supplies an audio signal generated from the application program to a WAVE input channel of the sound card, and the sound card is controlled to allow the audio signal to be reproduced through a speaker or a headset. Therefore, a user can utilize a variety of audio functions as desired.

However, if a variety of sound outputting programs, including a Windows Media Player or a game program, and so on, are executed at the same time in a computer system capable of executing audio functions, a plurality of audio signals are supplied to a WAVE input channel of the sound card. In response, the sound card mixes the plurality of audio signals, and outputs the sounds from the various programs simultaneously through the speaker. If a user desires to hear a sound generated only by one application program, the user has to activate, respectively, the other application programs and coordinate the volume manually through a volume coordinating menu of the respective application programs to remove the sound generated in the respective application programs that the user does not desire to hear.

### SUMMARY OF THE INVENTION

Accordingly, the present invention provides a computer system and a method of controlling the same, wherein only an audio signal which the user desires to hear is reproduced when a plurality of audio signals are generated.

Additional aspects and/or advantages of the invention will be set forth in part in the description which follows and, in part, will be obvious from the description, or may be learned by practice of the invention.

The present invention may be achieved by providing a method of controlling a computer system having an audio reproducing part receiving an audio signal from a plurality of application programs generating audio signals and reproducing the audio signal, comprising displaying a selection menu from which an application program with an audio signal desirous of being reproduced is allowed to be selected from among the plurality of the application programs; and supplying to the audio reproducing part only the audio signal from the application program selected in the displayed selection menu.

According to an aspect of the invention, the method further comprises storing information selected through the selection menu.

According to an aspect of the invention, the selection menu is displayed by selection of an icon for displaying the selection menu.

According to an aspect of the invention, the method further comprises displaying the selection menu in case of generation of an audio signal from any one of the application programs while the audio signal from one of the application programs is being reproduced.

According to another aspect of the present invention, a computer system having an audio reproducing part receiving an audio signal from a plurality of application programs generating audio signals and reproducing the audio signals, comprises an audio selection controller displaying a selection menu for selecting an application program having an audio signal desired for reproduction from among the plurality of the application programs and supplying to the audio reproducing part only the audio signal from the application program selected from the displayed selection menu.

According to an aspect of the invention, the audio selection controller stores therein information selected through the selection menu.

According to an aspect of the invention, the selection menu is displayed by selection of an icon for displaying the selection menu.

According to an aspect of the invention, the audio selection controller displays the selection menu in case of generation of an audio signal from any one of the application programs while the audio signal from one of the application programs is being reproduced.

### BRIEF DESCRIPTION OF THE DRAWINGS

The above and/or other aspects and advantages of the present invention will become apparent and more readily appreciated from the following description of the embodiments, taken in conjunction with the accompanying drawings of which:

FIG. 1 is a control block diagram of a computer system, according to an embodiment of the present invention;

FIG. 2 is an illustrative view of an audio selection menu in an audio selection program of the computer shown in FIG. 1; and

FIG. 3 is a flow chart of controlling the computer system shown in FIG. 1, according to an embodiment of the present invention.

### DETAILED DESCRIPTION OF THE PREFERRED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

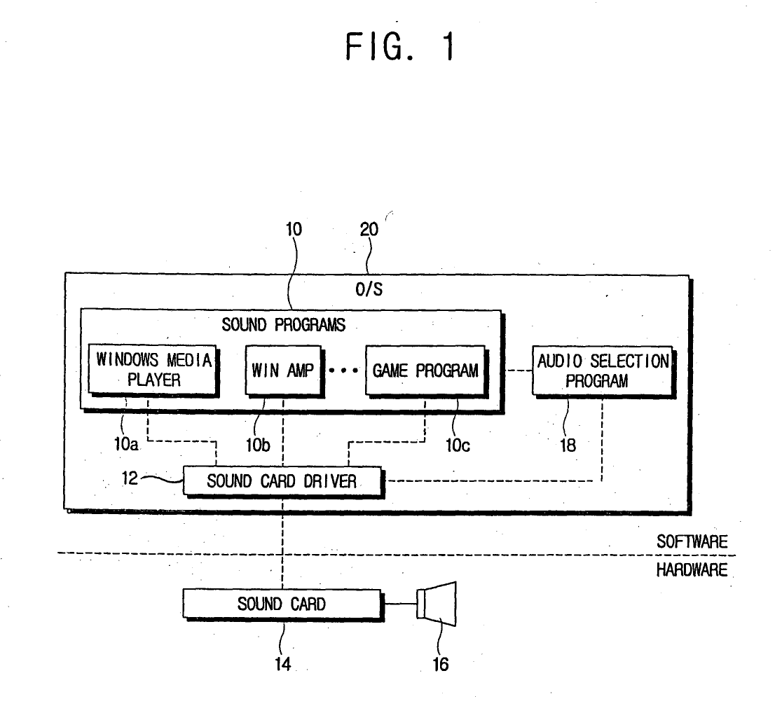

FIG. 1 is a control block diagram of a computer system according to an embodiment of the present invention. As depicted therein, the computer system comprises a hardware unit to execute an audio function comprising a sound card 14 to reproduce an audio and a speaker 16, and a software unit to operate (control) the hardware unit comprising a sound card driver 12, a plurality of sound programs 10 (i.e., sound generating programs 10a-10n) generating audio signals, and an audio selection program 18 selectively supplying the sound card 14 with only an audio signal from among a plurality of audio signals generated from the plurality of the sound programs 10.

Typically, the sound card 14 is installed on a main body of the computer system to reproduce the sound from MP3 data or a CD, and allow the user to appreciate moving pictures and enjoy games, and the sound is output through the speaker 16 connected to the sound card 14. The sound card 14 synthesizes and coordinates sounds through the sound chip and processes the digital sound data input through an input channel. The processed digital sound data is converted into an analog signal through the CODEC, amplified and output through the speaker 16.

The sound card driver 12 logically (i.e., as interface software) connects the sound card 14 to the computer system. The sound card driver 12, as software controlling the sound card 14, allows the sound card 14 to be operated (controlled) in response to execution of the sound programs 10, which are based on the operating system 20, so that the audio signals of the sound programs 10 can be supplied to a WAVE input channel of the sound card 14. In other words, if the user executes the sound programs 10 based on the operating system 20, for example, a Windows Media Player 10a, a Windows Amplifier program, or a game program 10c and so on, each sound program 10 transmits a control signal to the sound card driver 12. In response to the control signals by the sound programs 10, the sound card driver 12 sends a permit signal to permit use of the sound card 14 to each sound program 10, allowing the audio signal generated from the sound programs 10 to be supplied to the sound card 14. Then, the audio signals supplied to the sound card 14 are output through the speaker 16 by way of signal processing.

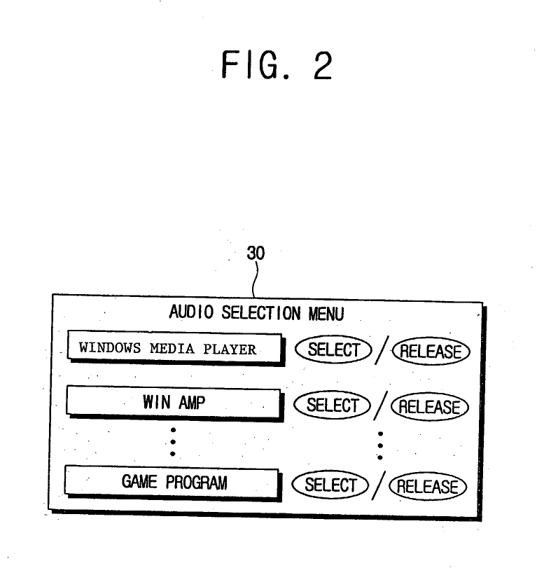

The audio selection program 18 is a program (software) on a higher level of abstraction than the sound card driver 12, with which only selected audio signals are reproduced from among a plurality of audio signals generated when the plurality of sound programs 10 are simultaneously executed. If the audio selection program 18 is executed, an audio selection menu 30 (see FIG. 2) displaying an information list concerning the plurality of sound programs 10 installed on the user's computer system is displayed. The user can select through the audio selection menu 30 one of the sound programs 10 that can generate an audio signal, which the user desires to output. For example, if the user desires an audio signal generated from the Windows Media Player 10a to be output and the user selects the Windows Media Player 10a in the audio selection menu 30, the audio signals generated from the sound programs 10b and 10c, which may be executed by the operating system 20 but not selected, are not supplied to the sound card 14. In this case, the sound card 14 cannot reproduce the audio signals from the sound programs 10b and 10c, because no audio signals are output by the programs 10b and 10c via the sound card driver 12 to the sound card 14. Meanwhile, the audio signal generated from the Windows Media Player 10a is supplied via the sound card driver 12 to the WAVE input channel of the sound card 14, passed through the signal processing operation by the sound card 14, and the processed audio signal is output through the speaker 16.

To describe in detail, the sound card driver 12 allows use of the sound card 14 according to a control signal supplied to the sound card driver 12 from the Windows Media Player 10a executed by the operating system 20, and in response to a permit signal by the sound card driver 12, the audio signal generated from the Windows Media Player 10a is supplied to the sound card 14. The audio signal is output through the speaker 16, passing through the reproduction process by the sound card 14.

However, if the other not selected sound programs 10b and 10c are executed, the sound card driver 12 is controlled by interrupting a control signal to be supplied by the sound programs 10b and 10c to the sound card driver 12, so that the audio signal is prevented from being supplied to the sound card 14. If a control signal is supplied to the sound card driver 12 in response to execution of the not selected sound programs 10b and 10c, according to another aspect of the invention, the audio signal can be prevented from being supplied to the sound card 14 by controlling (e.g., programming) the sound card driver 12 to not allow use of the sound card 14 (i.e., not providing permit signals to the sound programs 10b and 10c), because the concerned programs are not selected (i.e., according to a determination that the concerned sound programs 10 are not selected). That is, in the above-described two embodiments, transmission of the control and/or permit signals between the sound programs 10 and the sound card driver 12 is interrupted so that the audio signal of each not-selected (blocked) sound program 10 is not supplied to the sound card 14. Typically, the sound program 10, the audio selection program 18, and the sound card driver 12 are all executed based on the operating system 20.

FIG. 2 illustrates an example display screen of an audio selection menu 30 in the audio selection program 18. As shown therein, an information list of sound programs (sound generating programs) 10 installed on the user's computer system, from which the user is allowed to select a sound generating program 10, is displayed in the audio selection menu 30. Clicking any one of the sound generating programs 10 from the list or a selection icon corresponding to the sound generating program 10 indicates selection of an audio signal generated according to an execution of the selected sound generating program 10. Further, an icon for releasing a selection of the sound generating program 10 is provided. With the release function, reproduction of an audio signal from the selected program 10 is released and reproduction of an audio signal of another program 10 can be selected. As another embodiment, a release icon may not be separately provided, such that if a sound generating program 10 is selected through the audio selection menu 30, the corresponding selection icon can automatically be changed to a releasing icon for the selected sound generating program 10 upon clicking on the corresponding selection icon (i.e., the selection icon toggles between selection and release).

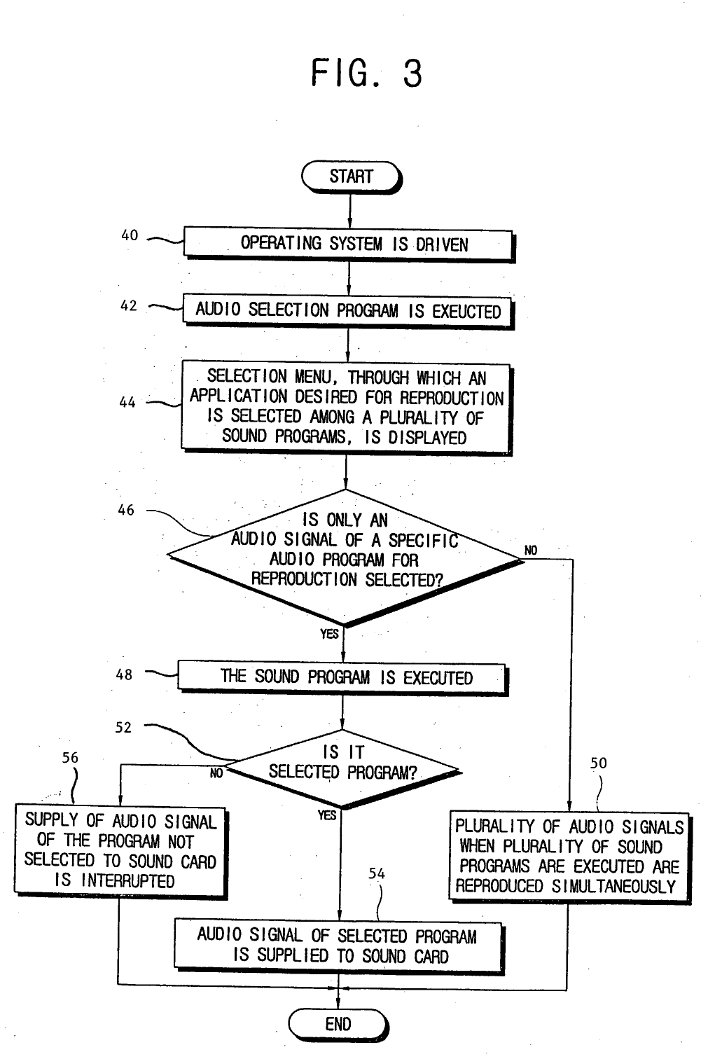

FIG. 3 is a flow chart of controlling the computer system shown in FIG. 1, according to an embodiment of the present invention. At operation 40, a computer system is first booted up and the operating system 20 is driven. At operation 42, if an icon for displaying the selection menu is selected by double clicking the icon with a mouse, the audio selection program 18 is executed. At operation 44, the audio selection menu 30 is displayed by the audio selection program 18 to allow the user to select the sound generating programs 10 installed on the user's computer system. If determined at operation 46 that an audio signal of any one of the sound generating programs 10 from among the plurality of the sound generating programs 10, e.g., the Windows Media Player 10a, is selected (i.e., whether there is a selected audio signal program 10) and, at operation 48, one of the sound generating programs 10 is executed, at operation 52, the audio selection program 18 determines whether the executed sound generating program 10 is the selected audio signal program 10 (i.e., whether there is an executing selected audio signal program 10). As a result of the determination, if, at operation 52, the Windows Media Player program 10a is the executing selected audio signal program 10, at operation 54, the audio selection program 18 controls the sound card driver 12 to allow the selected audio signal to be supplied to the sound card 14 to be reproduced. That is, at operation 54, a control signal is supplied to the sound card driver 12 from the Windows Media Player program 10a, and a permit signal with respect to use of the sound card 14 is sent to the Windows Media Player program 10a by the sound card driver 12, thereby allowing the audio signal generated from the Windows Media Player program 10a to be supplied via the sound card driver 12 to the sound card 14 and output through the speaker 16.

Meanwhile, if, at operation 52, it is determined that the executed sound generating program 10 is not the selected audio signal program 10, at operation 56, the audio selection program 18 controls the sound card driver 12 to interrupt supply of the audio signal generated by the executing not-selected (blocked) audio signal program 10 to the sound card 14. For example, if at operation 48, a sound generating program 10 other than the Windows Media Player 10a as the selected audio signal program, such as the game program 10c and the like, is executed, at operation 52, the audio selection program 18 recognizes this execution and determines that the game program 10c has not been selected to output sound (i.e., the game program 10c is an executing blocked audio signal program 10). Then, at operation 56, the audio selection program 18 controls the sound card driver 12 by interrupting a control and/or a permit signal between the game program 10c and the sound card driver 12 when the game program 10c is executing, to thereby allow an audio signal of the game program 10c not to be supplied to the sound card 14.

If, at operation 46, it is determined that no audio signal is selected in the audio selection menu 30 of the audio selection program 18, at operation 50, the computer system operates/functions as though the audio selection program 18 is not operating. That is, at operation 50, a plurality of audio signals will be reproduced at the same time if the plurality of sound generating programs 10 are executed.

Whenever each sound generating program 10 is executed and an audio signal is generated therefrom, the audio selection program 18 determines whether the executing sound generating program 10 is a selected audio signal program. If it is determined that the executing sound generating program 10 is not a selected audio signal program, the audio selection program 10 repeats processes of interrupting a control and/or permit signal between the sound card driver 12 and the sound program 10 so as to interrupt the output thereof. With this configuration, the sound card 14 is used only with selected sound generating application programs, whereby simultaneous output of a plurality of sounds will be prevented when a plurality of sound generating programs are executed, and only a sound as selected will be output.

Meanwhile, if the user releases audio signal selection of a sound generating program 10 selected by the user through the audio selection menu and selects another sound generating program 10, an audio signal generated from the newly selected sound generating program 10 is only reproduced and audio signals of the other sound generating programs 10 are not reproduced.

In the above-described embodiments, the user is allowed to select a sound generating program through the audio selection menu before the sound generating program is executed. However, the selection of the audio signal by the user may be made after execution of the sound generating program. Further, the audio selection menu may be displayed in the case that an audio signal of any one of the sound generating programs is generated while an audio signal of another one of the sound generating programs is being reproduced. That is, the audio selection menu can be displayed whenever any sound generating program is executed. Further, the present computer system may be configured to store selection information through the audio selection menu and when the computer system is rebooted up, the selected information can be read and only the audio signal of the selected sound generating programs can be reproduced. Through these operations, an audio signal of the selected sound generating program from among audio signals generated from a plurality of sound generating programs can be reproduced.

More particularly, as described above, the present invention provides a computer system and a method of controlling the same, wherein only an audio signal desired to be heard by the user can be reproduced when a plurality of audio signals are generated. Accordingly, the present invention provides a central application program audio signal (sound) blocker or selector. The processes of the invention as shown in FIG. 3 and provided in a computer can be implemented in software and/or computing hardware. Typically, the audio selection program 18 is software that embodies FIG. 3 processes. In particular, a computer according to present invention comprises a data storage, such as magnetic and optical discs, RAM, ROM, etc., on which the audio selection program 18 as processes of the invention can be stored and executed.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A method of controlling a computer system having an audio reproducing part receiving audio signals from a plurality of application programs generating the audio signals and reproducing the audio signals, the method comprising:
displaying a selection menu allowing selection of at least one of the application programs with one the audio signals to be reproduced; and
supplying only the audio signal from the selected application program to the audio reproducing part.

2. The method according to claim 1, further comprising:
storing information selected through the selection menu; and
supplying the audio signals from the application programs to the audio reproducing part according to the stored information, upon booting of the computer system.

3. The method according to claim 1, wherein the selection menu is displayed by selecting an icon for displaying the selection menu before or after execution of the application program.

4. The method according to claim 1, further comprising displaying the selection menu when the audio signal from any one of the application programs is generated while the audio signal from another one of the application programs is being reproduced.

5. A computer system having an audio reproducing part receiving audio signals from a plurality of application programs generating audio signals and reproducing the audio signal, the computer system comprising:
an audio selection controller displaying a selection menu allowing selection of at least one of the application programs with one of the audio signals to be reproduced; and
supplying only the audio signal from the selected application program to the audio reproducing part.

6. The computer system according to claim 5, wherein the audio selection controller stores therein information selected through the selection menu and upon booting of the computer system the audio selection controller supplies the audio signals from the application programs to the audio reproducing part according to the stored information.

7. The computer system according to claim 5, wherein the selection menu is displayed by selecting an icon for displaying the selection menu before or after execution of the application program.

8. The computer system according to claim 5, wherein the audio selection controller displays the selection menu when the audio signal from any one of the application programs is generated while the audio signal from another one of the application programs is being reproduced.

9. The method of claim 1, wherein the displaying of the selection menu comprises displaying application program icons toggling between selection and release to select and release audio signal reproduction of the application programs.

10. The computer system of claim 5, wherein the audio selection controller displays as the selection menu application program icons toggling between selection and release to select and release audio signal reproduction of the application programs.

11. A computer readable storage controlling a computer according to a stored process of:
displaying a selection menu allowing selection of an application program with an audio signal to be reproduced from among a plurality of audio signal generating application programs; and
supplying only the audio signal from the selected application program as a selected audio signal program to an audio reproducing system of the computer.

12. The computer readable storage of claim 11, wherein the supplying of the audio signal comprises:
determining whether an audio signal generating application program is the selected audio signal program; and
interrupting an audio signal of a blocked audio signal program to the audio reproducing system according to the determining.

13. A computer, comprising:
a programmed computer processor allowing central selection of blocking output of respective audio signals generated by two or more application programs.
